(19) United States
(12) Patent Application Publication
(10) Pub. No.: US 2024/0220142 A1
(43) Pub. Date: Jul. 4, 2024

(54) MEMORY DEVICE AND METHOD OF OPERATING THE SAME

(71) Applicant: SK hynix Inc., Icheon-si Gyeonggi-do (KR)

(72) Inventor: Jung Ho PARK, Icheon-si Gyeonggi-do (KR)

(73) Assignee: SK hynix Inc., Icheon-si Gyeonggi-do (KR)

(21) Appl. No.: 18/346,037

(22) Filed: Jun. 30, 2023

(30) Foreign Application Priority Data
Jan. 3, 2023 (KR) 10-2023-0000666

(51) Int. Cl. G06F 3/06; G06F 13/10

(52) U.S. Cl. CPC G06F 3/064; G06F 3/0604; G06F 3/0655; G06F 3/0679; G06F 13/10

(57) ABSTRACT

A memory device, and a method of operating the same, includes a memory block to which first and second word line groups are coupled, and to which a first dummy line group disposed between the first and second word line groups is coupled. The memory device also includes a peripheral circuit configured to program memory cells coupled to a selected word line of the first or second word line group. The peripheral circuit is configured to, when the selected word line is included in the second word line group, when a program voltage is applied to the selected word line, apply a first pass voltage to unselected word lines included in the first and second word line groups and to dummy lines included in the first dummy line group.

### CROSS-REFERENCE TO RELATED APPLICATION

The present application claims priority under 35 U.S.C. § 119(a) to Korean patent application number 10-2023-0000666 filed on Jan. 3, 2023, in the Korean Intellectual Property Office, the entire disclosure of which is incorporated by reference herein.

### BACKGROUND

### 1. Technical Field

Various embodiments of the present disclosure generally relate to a memory device and a method of operating the memory device, and more particularly, to a memory device configured to perform a program operation and a method of operating the memory device.

### 2. Related Art

A memory device may include a memory cell array in which data is stored, a peripheral circuit which performs a program operation, a read operation, or an erase operation, and a control circuit which controls the peripheral circuit.

The memory cell array may include a plurality of memory blocks, each of which may include a plurality of memory cells. A memory device having a three-dimensional (3D) structure may include memory cells stacked on a substrate. For example, in the memory device having a 3D structure, each of memory blocks may include a plurality of strings extending in a vertical direction from the substrate, and each of the plurality of strings may include a plurality of memory cells.

During a program operation on a memory block selected from among the plurality of memory blocks, selected memory cells included in a page selected from among a plurality of pages included in the selected memory block may be programmed. A word line coupled to memory cells in the selected page may be a selected word line, and word lines coupled to memory cells in unselected pages may be unselected word lines.

While a program operation is performed on the selected memory cells, the threshold voltages of memory cells coupled to the unselected word lines may be maintained without change. However, the threshold voltages of unselected memory cells may be changed due to the influence of voltages applied to the selected word line and the unselected word lines. In this case, the reliability of the program operation of the memory device may be deteriorated.

### SUMMARY

Various embodiments of the present disclosure are directed to a memory device that is capable of improving the reliability of a program operation and a method of operating the memory device.

An embodiment of the present disclosure may provide for a memory device. The memory device may include a memory block to which first and second word line groups are coupled, and to which a first dummy line group disposed between the first and second word line groups is coupled. The memory device may also include a peripheral circuit configured to program memory cells coupled to a selected word line of the first or second word line group. The peripheral circuit is configured to, when the selected word line is included in the second word line group, when a program voltage is applied to the selected word line, apply a first pass voltage to unselected word lines included in the first and second word line groups and to dummy lines included in the first dummy line group. The peripheral circuit is configured to, when the selected word line is included in the first word line group, when the program voltage is applied to the selected word line, allow first unselected word lines disposed between the selected word line and the first dummy line group to float, apply the first pass voltage to second unselected word lines other than the selected word line and the first unselected word lines among word lines included in the first word line group, and apply a second pass voltage higher than the first pass voltage to the dummy lines included in the first dummy line group.

An embodiment of the present disclosure may provide for a method of operating a memory device. The method may include: when a first word line group and a second word line group are located between a source line and bit lines, wherein the first word line group is adjacent to the source line, and the second word line group is adjacent to bit lines, and a selected word line is included in the first word line group, applying a program voltage to the selected word line; when the program voltage is applied to the selected word line, applying a second pass voltage higher than the first pass voltage to a first dummy line group between the first and second word line groups; when the program voltage is applied to the selected word line, allowing unselected word lines between the selected word line and the first dummy line group to float.

An embodiment of the present disclosure may provide for a memory device. The memory device may include a memory block to which first and second word line groups are coupled, and to which a first dummy line group disposed between the first and second word line groups is coupled. The memory device may also include a peripheral circuit configured to program memory cells coupled to a selected word line of the first or second word line group. The peripheral circuit is configured to, when the selected word line is included in the second word line group, when a program voltage is applied to the selected word line, apply a first pass voltage to unselected word lines included in the first and second word line groups and to dummy lines included in the first dummy line group. The peripheral circuit is configured to, when the selected word line is included in the first word line group, when the program voltage is applied to the selected word line, apply compensation voltages higher than the first pass voltage to first unselected word lines disposed between the selected word line and the first dummy line group, apply the first pass voltage to second unselected word lines other than the selected word line and the first unselected word lines among word lines included in the first word line group, and apply a second pass voltage higher than the first pass voltage to the dummy lines included in the first dummy line group.

An embodiment of the present disclosure may provide for a method of operating a memory device. The method may include: when a first word line group and a second word line group are located between a source line and bit lines, wherein the first word line group is adjacent to the source line, and the second word line group is adjacent to bit lines, and a selected word line is included in the first word line group, applying a program voltage to the selected word line; when the program voltage is applied to the selected word line, applying a first pass voltage to the second word line group, when the program voltage is applied to the selected word line, applying a second pass voltage higher than the first pass voltage to a first dummy line group between the first and second word line groups; and when the program voltage is applied to the selected word line, applying compensation voltages higher than the first pass voltage to unselected word lines between the selected word line and the first dummy line group.

### BRIEF DESCRIPTION OF THE DRAWINGS

FIG. 1 is a diagram illustrating a memory device according to an embodiment of the present disclosure.

FIG. 2 is a diagram illustrating a memory block according to an embodiment of the present disclosure.

FIG. 3 is a diagram illustrating a partial cross-section of a memory block.

FIGS. 4A, 4B, 5A, 5B, 6A, 6B, 7A, and 7B are diagrams illustrating a program operation according to a first embodiment of the present disclosure.

FIGS. 8A and 8B are diagrams illustrating a program operation according to a second embodiment of the present disclosure.

FIGS. 9A and 9B are diagrams illustrating a program operation according to a third embodiment of the present disclosure.

FIGS. 10A and 10B are diagrams illustrating a program operation according to a fourth embodiment of the present disclosure.

FIGS. 11A and 11B are diagrams illustrating a program operation according to a fifth embodiment of the present disclosure.

FIG. 12 is a diagram illustrating a memory card system to which a memory device according to the present disclosure is applied.

FIG. 13 is a diagram illustrating a solid state drive (SSD) system to which a memory device according to the present disclosure is applied.

### DETAILED DESCRIPTION

Specific structural or functional descriptions, disclosed herein, are exemplified to describe embodiments according to the concept of the present disclosure. The embodiments according to the concept of the present disclosure should not be construed as being limited to embodiments described below, and may be modified in various forms and replaced with other equivalent embodiments.

Hereinafter, it will be understood that, although the terms “first” and “second” may be used herein to describe various elements, these elements should not be limited by these terms. The terms are used to distinguish one element from other elements and not to imply a number or order of elements.

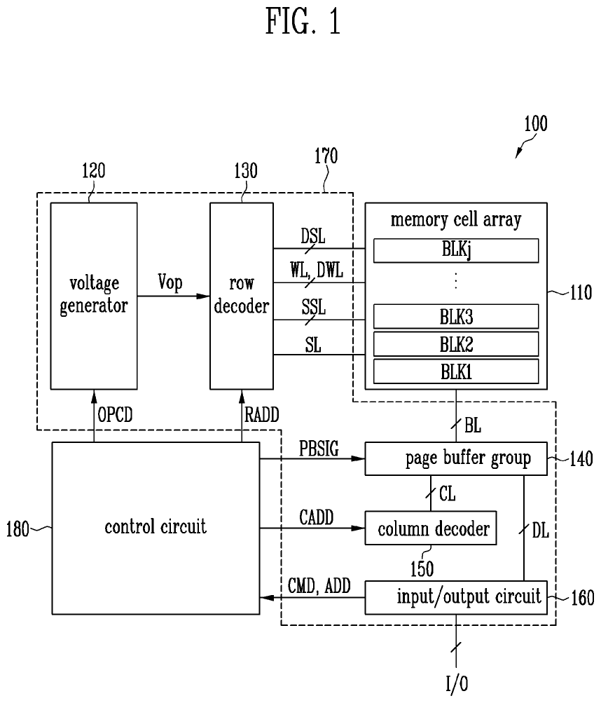

FIG. 1 is a diagram illustrating a memory device according to an embodiment of the present disclosure.

Referring to FIG. 1, a memory device 100 may include a memory cell array 110, a peripheral circuit 170, and a control circuit 180.

The memory cell array 110 may include first to j-th memory blocks BLK1 to BLKj. Each of the first to j-th memory blocks BLK1 to BLKj may include a plurality of memory cells in which data can be stored. Drain select lines DSL, word lines WL, dummy lines DWL, source select lines SSL, and a source line SL may be coupled to each of the first to j-th memory blocks BLK1 to BLKj. Bit lines BL may be coupled in common to the first to j-th memory blocks BLK1 to BLKj. The first to j-th memory blocks BLK1 to BLKj may be formed in a three-dimensional (3D) structure. Each of the memory blocks having a 3D structure may include memory cells stacked on a substrate.

According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuit 170 may perform a program operation of storing data in the memory cell array 110, a read operation of outputting data stored in the memory cell array 110, and an erase operation of erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop required for a program operation, a read operation, or an erase operation in response to an operation code OPCD. For example, the voltage generator 120 may generate program voltages, turn-on voltages, turn-off voltages, negative voltages, verify voltages, read voltages, pass voltages, compensation voltages or erase voltages in response to the operation code OPCD. The operating voltages Vop generated by the voltage generator 120 may be applied to the drain select lines DSL, the word lines WL, the dummy lines DWL, the source select lines SSL, and the source line SL of the selected memory block through the row decoder 130.

The program voltages may be voltages that are applied to the selected word line, among the word lines WL, during a program operation, and may be used to increase the threshold voltages of memory cells coupled to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off drain select transistors or source select transistors. For example, the turn-off voltage may be set to 0 V. The negative voltages may be set to voltages lower than 0 V. The verify voltages may be used for a verify operation of determining whether the threshold voltages of the selected memory cells have increased up to target levels. The verify voltages may be set to various levels depending on the target levels, and may be applied to the selected word line. The read voltages may be applied to the selected word line during a read operation on the selected memory cells. The pass voltages may be voltages that are applied to unselected word lines or dummy lines during a program operation, and may be used to turn on memory cells coupled to the unselected word lines or on dummy cells coupled to the dummy lines. The compensation voltages may be voltages that are applied to word lines adjacent to the selected word line during a program operation, and may be used to reduce a voltage difference between channels corresponding to the selected word line and the adjacent word lines. The compensation voltages may be set to have different levels depending on the distance to the selected word line. The erase voltages may be used for an erase operation of erasing the memory cells included in the selected memory block, and may be applied to the source line SL.

The voltage generator 120 may control the levels of voltages that are applied to the drain select lines DSL, the word lines WL, the dummy lines DWL, the source select lines SSL, and the source line SL, and the times during which the voltages are output, in response to the operation code OPCD. The voltage generator 120 may discharge the lines to which the operating voltages Vop are applied, and may control the times during which the lines are discharged. The voltage generator 120 may allow the selected lines to float.

The row decoder 130 may transfer the operating voltages Vop to the drain select lines DSL, the word lines WL, the source select lines SSL, and the source line SL, which are coupled to a memory block selected in response to a row address RADD. For example, the row decoder 130 may be coupled to the voltage generator 120 through global lines, and may be coupled to the first to j-th memory blocks BLK1 to BLKj through the drain select lines DSL, the word lines WL, the dummy lines DWL, the source select lines SSL, and the source line SL.

The page buffer group 140 may include page buffers (not illustrated) coupled to the first to j-th memory blocks BLK1 to BLKj through the bit lines BL. During a program operation, program data transferred from the input/output circuit 160 may be stored in the page buffer group 140. The page buffer group 140 may apply a program-enable voltage or a program-inhibit voltage to the bit lines BL based on the program data in response to page buffer control signals PBSIG. During a verify operation, the page buffer group 140 may sense the currents or voltages of the bit lines BL varying with the threshold voltages of the selected memory cells, and may store sensed data.

The column decoder 150 may be configured such that data is transferred between the page buffer group 140 and the input/output circuit 160 in response to a column address CADD. For example, the column decoder 150 may be coupled to the page buffer group 140 through column lines CL, and may transmit enable signals through the column lines CL. The page buffers (not illustrated) included in the page buffer group 140 may receive or output data through data lines DL in response to the enable signals.

The input/output circuit 160 may receive or output a command CMD, an address ADD, or data through input/output lines I/O. For example, the input/output circuit 160 may transmit the command CMD and the address ADD, received from an external controller through the input/output lines I/O, to the control circuit 180, and may transmit the data, received from the external controller through the input/output lines I/O, to the page buffer group 140. Alternatively, the input/output circuit 160 may output data, received from the page buffer group 140, to the external controller through the input/output lines I/O.

The control circuit 180 may output the operation code OPCD, the row address RADD, the page buffer control signals PBSIG, and the column address CADD in response to the command CMD and the address ADD. For example, when the command CMD input to the control circuit 180 is a command corresponding to a program operation, the control circuit 180 may control the peripheral circuit 170 so that a program operation is performed on a memory block selected by the address ADD. When the command CMD input to the control circuit 180 is a command corresponding to a read operation, the control circuit 180 may control the peripheral circuit 170 so that a read operation is performed on a memory block selected by the address and read data is output. When the command CMD input to the control circuit 180 is a command corresponding to an erase operation, the control circuit 180 may control the peripheral circuit 170 so that an erase operation is performed on a selected memory block.

During the program operation according to the present embodiment, the control circuit 180 may control the peripheral circuit 170 to vary voltages that are applied to the unselected word lines and voltages that are applied to the dummy lines DWL depending on the position of the selected word line.

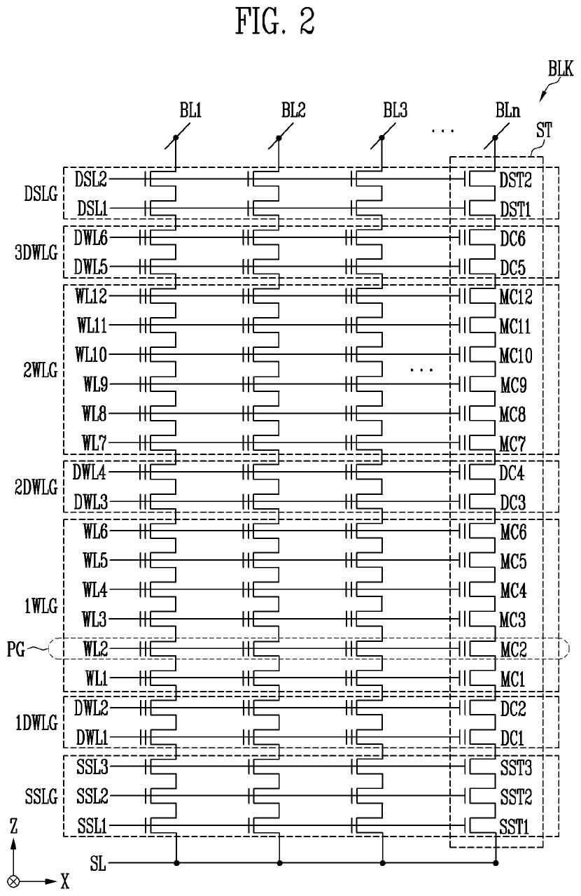

FIG. 2 is a diagram illustrating a memory block according to an embodiment of the present disclosure.

Referring to FIG. 2, the memory block BLK may be any one of the first to j-th memory blocks BLK1 to BLKj illustrated in FIG. 1. The memory block BLK may include strings ST coupled between first to n-th bit lines BL1 to BLn and a source line SL. For example, the strings ST may be coupled in common to the source line SL and may be coupled to the first to n-th bit lines BL1 to BLn, respectively. The structure of the string ST coupled between the n-th bit line BLn and the source line SL will be described by way of example.

The string ST may include source select transistors, dummy cells, memory cells, and drain select transistors which are coupled in series to each other between the source line SL and the n-th bit line BLn. For example, the string ST may include first to third source select transistors SST1 to SST3, first and second dummy cells DC1 and DC2, first to sixth memory cells MC1 to MC6, third and fourth dummy cells DC3 and DC4, seventh to twelfth memory cells MC7 to MC12, fifth and sixth dummy cells DC5 and DC6, and first and second drain select transistors DST1 and DST2. Because the string ST illustrated in FIG. 2 is illustrated as an example, the numbers of source select transistors, the dummy cells, the memory cells, and the drain select transistors that are included in the string ST may be changed depending on the memory device.

The first to third source select transistors SST1 to SST3 may electrically connect or disconnect the source line SL to or from channels of the strings ST. Gates of the first source select transistors SST1 included in different strings ST may be coupled to the first source select line SSL1, gates of the second source select transistors SST2 may be coupled to the second source select line SSL2, and gates of the third source select transistors SST3 may be coupled to the third source select line SSL3. The first to third source select lines SSL1 to SSL3 may be included in a source select line group SSLG. During a program operation, a turn-on voltage or a turn-off voltage may be simultaneously applied to the first to third source select lines SSL1 to SSL3 included in the source select line group SSLG. During the program operation, a precharge voltage a ground voltage may be applied to the source line SL.

The first and second dummy cells DC1 and DC2 may be used to electrically connect or disconnect the third source select transistors SST3 to or from the channels of the strings ST. Furthermore, the first and second dummy cells DC1 and DC2 may also be used to prevent electrical interference between the source select line group SSLG and the first word line WL1. Therefore, dummy data instead of normal data may be stored in the first and second dummy cells DC1 and DC2. Gates of the first dummy cells DC1 included in different strings ST may be coupled to a first dummy line DWL1, and gates of the second dummy cells DC2 may be coupled to a second dummy line DWL2. The first and second dummy lines DWL1 and DWL2 may be included in a first dummy line group 1DWLG. During a program operation, a first pass voltage or a ground voltage may be applied to the first and second dummy lines DWL1 and DWL2 included in the first dummy line group 1DWLG. The first pass voltage may be a positive voltage higher than the ground voltage, and may be set to a level that enables the dummy cells to be turned on.

The first to sixth memory cells MC1 to MC6 and the seventh to twelfth memory cells MC7 to MC12 may store the normal data. Gates of the first to sixth memory cells MC1 to MC6 and the seventh to twelfth memory cells MC7 to MC12 that are included in different strings ST may be coupled to the first to sixth word lines WL1 to WL6 and the seventh to twelfth word lines WL7 to WL12, respectively. For example, the gates of the first memory cells MC1 included in different strings ST may be coupled to the first word line WL1, and the gates of the second memory cells MC2 included in different strings ST may be coupled to the second word line WL2. In this way, the third to twelfth memory cells MC3 to MC12 may be coupled to the third to twelfth word lines WL3 to WL12, respectively. The first to sixth memory cells MC1 to MC6 may be included in a first word line group 1WLG, and the seventh to twelfth memory cells MC7 to MC12 may be included in a second word line group 2WLG. A group of memory cells coupled to the same word line may form a page (PG), and a program operation may be performed on a page basis.

The third and fourth dummy cells DC3 and DC4 may be coupled between the first and second word line groups 1WLG and 2WLG. For example, the third dummy cells DC3 may be coupled between the sixth memory cells MC6 and the fourth dummy cells DC4, and the fourth dummy cells DC4 may be coupled between the third dummy cells DC3 and the seventh memory cells MC7. The third and fourth dummy cells DC3 and DC4 may be used to prevent interference between the memory cells included in the first and second word line groups 1WLG and 2WLG. Therefore, dummy data instead of normal data may be stored in the third and fourth dummy cells DC3 and DC4. Gates of the third dummy cells DC3 included in different strings ST may be coupled to a third dummy line DWL3, and gates of the fourth dummy cells DC4 may be coupled to a fourth dummy line DWL4. The third and fourth dummy lines DWL3 and DWL4 may be included in a second dummy line group 2DWLG. During a program operation, a second or third pass voltage or the ground voltage may be applied to the third and fourth dummy lines DWL3 and DWL4 included in the second dummy line group 2DWLG. The second pass voltage may be set to have a level higher than that of the first pass voltage, and the third pass voltage may be set to have a level higher than that of the second pass voltage.

The fifth and sixth dummy cells DC5 and DC6 may be used to electrically connect or disconnect the first drain select transistors DST1 to or from the channels of the strings ST. Furthermore, the fifth and sixth dummy cells DC5 and DC6 may also be used to prevent electrical interference between the twelfth word line WL12 and a drain select line group DSLG. Therefore, dummy data may be stored in the fifth and sixth dummy cells DC5 and DC6. Gates of the fifth dummy cells DC5 included in different strings ST may be coupled to a fifth dummy line DWL5, and gates of the sixth dummy cells DC6 may be coupled to a sixth dummy line DWL6. The fifth and sixth dummy lines DWL5 and DWL6 may be included in a third dummy line group 3DWLG. During a program operation, a first pass voltage or a ground voltage may be applied to the fifth and sixth dummy lines DWL5 and DWL6 included in the third dummy line group 3DWLG.

The first and second drain select transistors DST1 and DST2 may be configured to electrically connect or disconnect the channels of the strings ST to or from the first to n-th bit lines BL1 to BLn. The gates of the first drain select transistors DST1 included in different strings ST may be coupled to the first drain select line DSL1, and the gates of the second drain select transistors DST2 may be coupled to the second drain select line DSL2. The first and second drain select lines DSL1 and DSL2 may be included in a drain select line group DSLG. During a program operation, a turn-on voltage or a turn-off voltage may be simultaneously applied to the first and second drain select lines DSL1 and DSL2 included in the drain select line group DSLG. During the program operation, the program-enable voltage or the program-inhibit voltage may be selectively applied to the first to n-th bit lines BL1 to BLn.

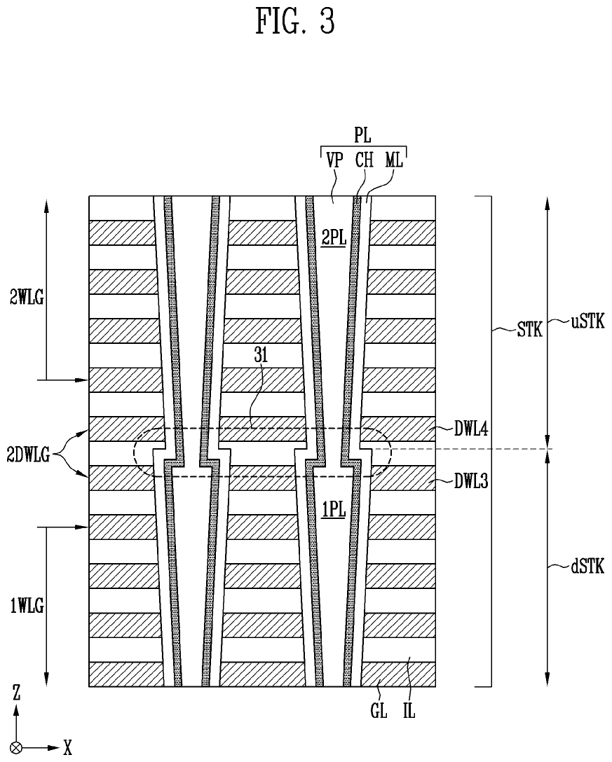

FIG. 3 is a diagram illustrating a partial cross-section of a memory block.

Referring to FIG. 3, a memory block may include a stacked structure STK in which gate lines GL and insulating layers IL are alternately stacked, and plugs PL penetrating the stacked structure STK in a vertical direction (Z). The stacked structure STK may include a lower structure dSTK and an upper structure uSTK stacked on the lower structure dSTK. Each plug PL may include a first plug 1PL and a second plug 2PL stacked on the first plug 1PL. The first plug 1PL may vertically penetrate the lower structure dSTK, and the second plug 2PL may vertically penetrate the upper structure uSTK. Each of the first and second plugs 1PL and 2PL may include a memory layer ML, a channel layer CH, and a vertical pillar VP, each of which extends in a vertical direction.

The memory layer ML may be formed in a cylindrical shape along the inner walls of the first and second plugs 1PL and 2PL. For example, the memory layer ML may include a tunnel isolation layer formed in a cylindrical shape, a charge trap layer formed in a cylindrical shape along the inner surface of the tunnel insulating layer, and a blocking layer formed in a cylindrical shape along the inner surface of the charge trap layer. The tunnel insulating layer and the blocking layer may be formed of an oxide layer made of an insulating material. The charge trap layer may be a layer for trapping electrons, and may be formed of a nitride layer. The channel layer CH may be a layer in which electrons or holes can be moved in a string, and may be formed of a polysilicon layer. The channel layer CH may be formed in a cylindrical shape along the inner surface of the memory layer ML. The vertical pillar VP may be formed in a cylindrical shape along the inner surface of the channel layer CH, and may be made of an insulating material or a conductive material.

Because the upper structure uSTK and the second plug 2PL are formed on the lower structure dSTK and the first plug 1PL due to the order of a manufacturing process, the width of the first plug 1PL may increase in a direction from below to above, the width of the second plug 2PL may also increase in a direction from below to above, and the width of the lowermost portion of the second plug 2PL may be less than that of the uppermost portion of the first plug 1PL. Therefore, the difference between the widths of the cells may be largest in an area 31 in which the first and second plugs 1PL and 2PL contact each other. As the difference between the widths of the cells adjacent to each other is increased, differences may also occur in the electrical characteristics of the cells, and thus cells adjacent to the area 31 in which the first and second plugs 1PL and 2PL contact each other may be designated as the third and fourth dummy cells (e.g., DC3 and DC4 of FIG. 2). Therefore, the gate lines GL formed in the area 31 in which the first and second plugs 1PL and 2PL contact each other may be designated as third and fourth dummy lines DWL3 and DWL4. In other words, the gate lines GL formed in the area 31 in which the first and second plugs 1PL and 2PL contact each other may be included in the second dummy line group 2DWLG.

In order to prevent the deterioration of electrical characteristics attributable to the above-described structure and the deterioration of reliability of a program operation attributable to the reduction of the size of a memory block, voltages that are applied to dummy lines and unselected word lines in the program operation may be controlled. A program operation according to the present embodiment will be described in detail below.

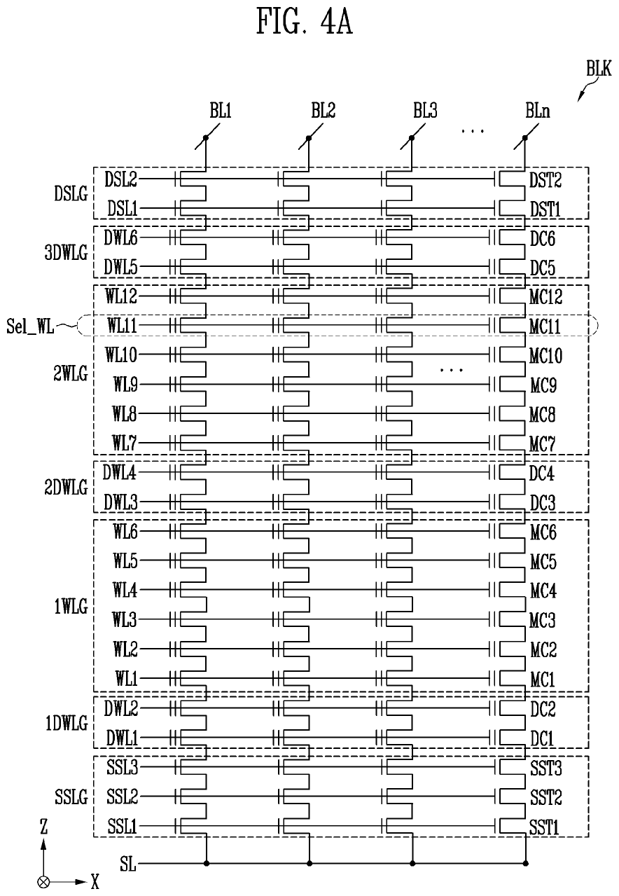

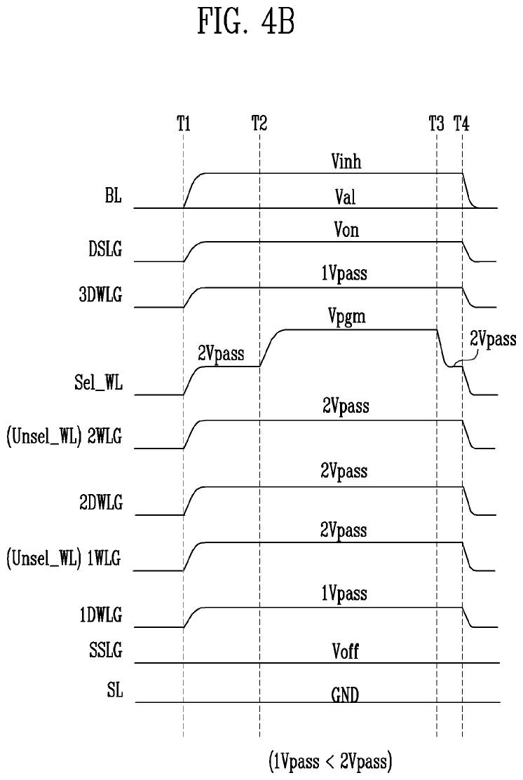

FIGS. 4A to 7B are diagrams illustrating a program operation according to a first embodiment of the present disclosure.

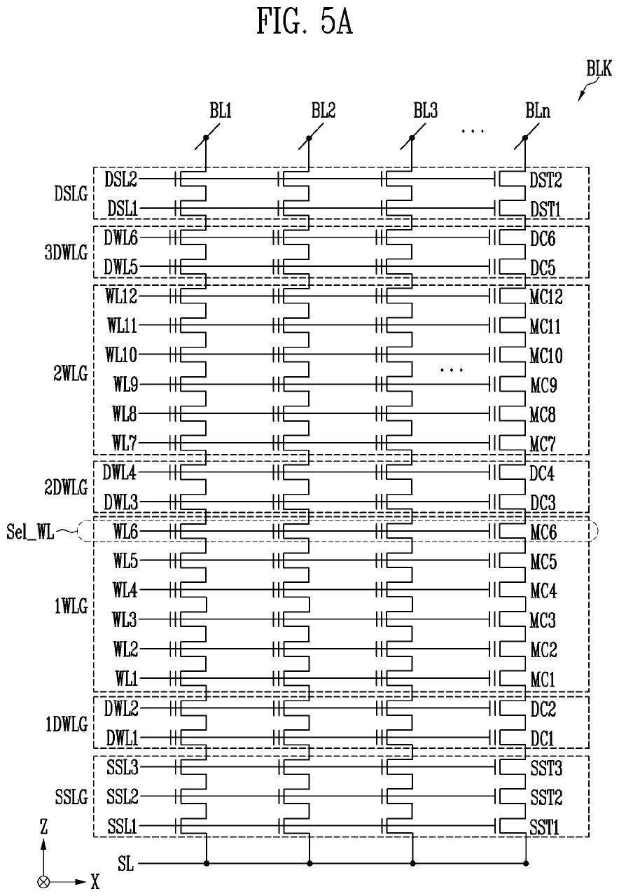

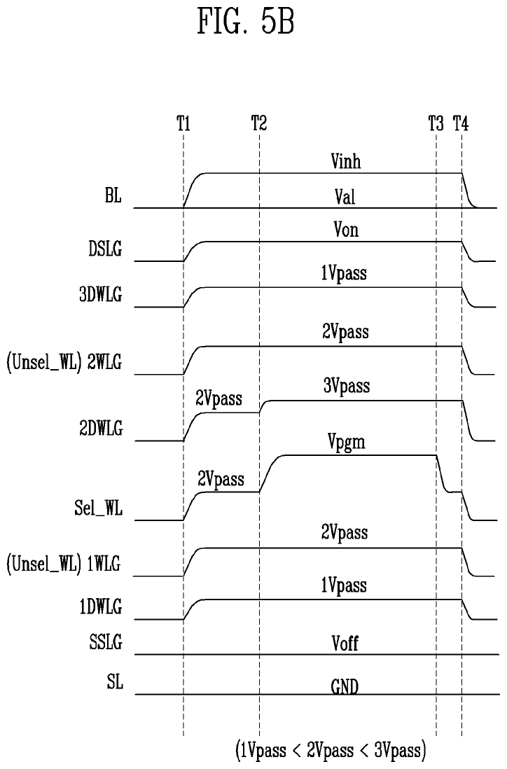

Among FIGS. 4A to 7B, FIGS. 4A and 4B are diagrams for describing a program operation in the case where a selected word line Sel_WL is included in a second word line group 2WLG, and FIGS. 5A to 7B are diagrams for describing a program operation in the case where the selected word line Sel_WL is included in a first word line group 1WLG.

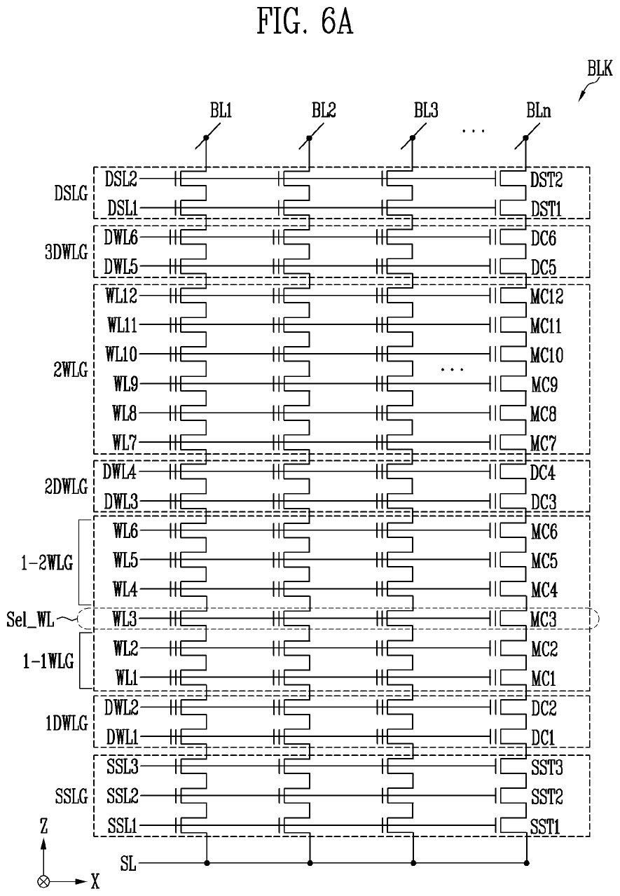

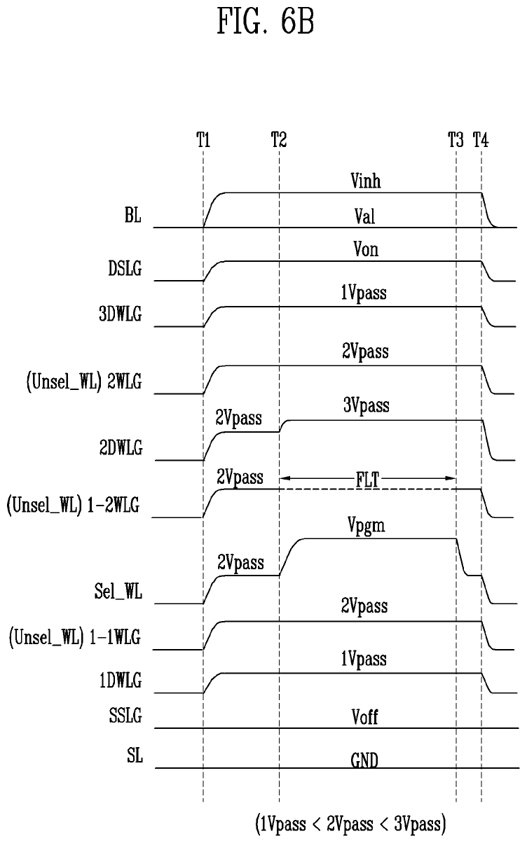

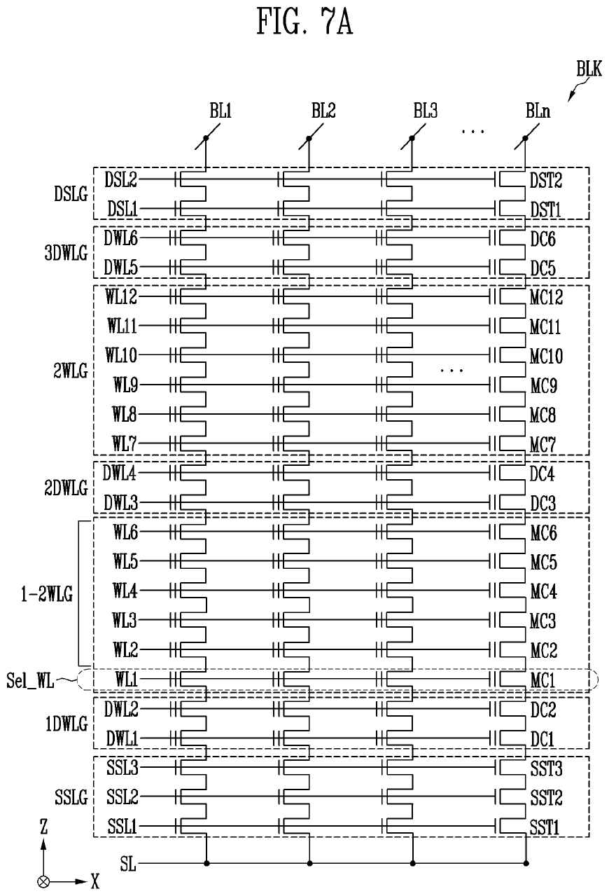

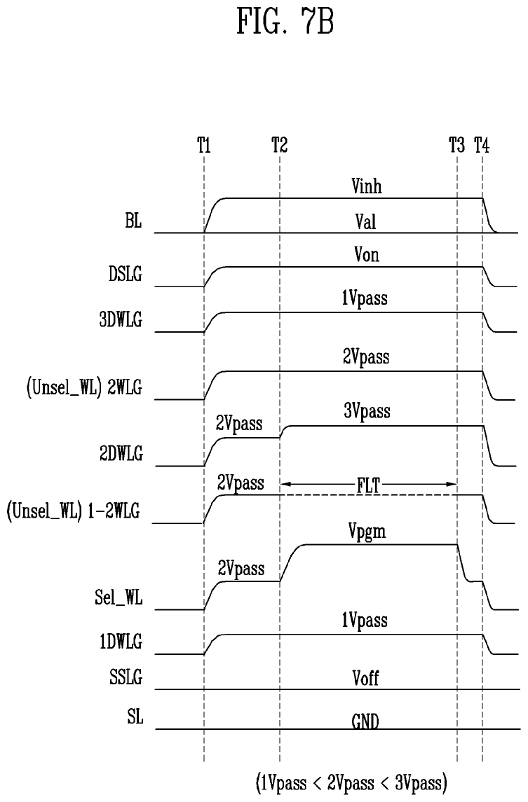

Among FIGS. 5A to 7B, FIGS. 5A and 5B are diagrams for describing a program operation in the case where the selected word line Sel_WL is adjacent to a second dummy line group 2DWLG, FIGS. 6A and 6B are diagrams for describing a program operation in the case where the selected word line Sel_WL is disposed between first and second dummy line groups 1DWLG and 2DWLG, and FIGS. 7A and 7B are diagrams for describing a program operation in the case where the selected word line Sel_WL is adjacent to the first dummy line group 1DWLG.

Referring to FIGS. 4A and 4B, the program operation may be performed on a page basis. A selected page may include memory cells coupled to the selected word line Sel_WL. The program operation according to the first embodiment may be performed in a direction from a drain select line group DSLG to a source select line group SSLG. For example, a twelfth word line WL12 may be the first selected word line Sel_WL, and a first word line WL1 may be the last selected word line Sel_WL.

When the selected word line Sel_WL is included in the second word line group 2WLG between second and third dummy line groups 2DWLG and 3DWLG, the number of programmed memory cells is relatively small, and thus channel boosting for increasing the channel voltages of unselected strings may be easily performed. Therefore, the voltages applied to the first to third dummy line groups 1DWLG to 3DWLG and the unselected word lines Unsel_WL may be maintained at certain levels without being varied. The voltages applied to the lines during the program operation are sequentially described as follows.

During a period from T1 to T2, a program-enable voltage Val or a program-inhibit voltage Vinh may be applied to the bit lines BL. For example, the program-enable voltage Val may be applied to selected bit lines coupled to selected strings, and the program-inhibit voltage Vinh may be applied to unselected bit lines coupled to unselected strings.

The program-enable voltage Val may be set to a level equal to that of a ground voltage GND, and the program-inhibit voltage Vinh may be set to a positive voltage higher than the program-enable voltage Val. Although, in FIG. 4B, the program-inhibit voltage Vinh is illustrated as being applied to bit lines BL at a time point T1, the program-inhibit voltage Vinh may be applied to the bit lines BL from before the time point T1.

In order to control the channel voltages of strings according to the program-enable voltage Val or the program-inhibit voltage Vinh applied to the bit lines BL, a turn-on voltage Von may be applied to the drain select line group DSLG. The turn-on voltage Von may be set to a positive voltage so as to turn on first and second drain select transistors DST1 and DST2. When the ground voltage GND is applied to the source line SL, a turn-off voltage Voff may be applied to the source select line group SSLG so as to electrically disconnect the source line SL from the channels of the strings. The turn-off voltage Voff may be set to the ground voltage GND so as to turn off the first to third source select transistors SST1 to SST3.

A first pass voltage 1Vpass may be applied to first and third dummy line groups 1DWLG and 3DWLG, and a second pass voltage 2Vpass, higher than the first pass voltage 1Vpass, may be applied to the second dummy line group 2DWLG. In order to form channels in the strings, the second pass voltage Vpass2 may be applied to the unselected word lines Unsel_WL included in first and second word line groups 1WLG and 2WLG, and may also be applied to the selected word line Sel_WL included in the second word line group 2WLG. Due to the voltages applied to the respective lines during the period from T1 to T2, the channel voltages of the unselected strings may be increased.

During a period from T2 to T3, a program voltage Vpgm may be applied to the selected word line Sel_WL. Because the program voltage Vpgm is a voltage for increasing the threshold voltages of the selected memory cells, it may be set to a voltage higher than the second pass voltage 2Vpass. While the program voltage Vpgm is applied to the selected word line Sel_WL, the voltages applied to the remaining lines may be maintained at the voltages applied during the period from T1 to T2.

A period from T3 to T4 may be a period during which the potential of the selected word line Sel_WL is to be stepwise decreased. For example, the voltage of the selected word line Sel_WL may be decreased to the second pass voltage 2Vpass.

When a time point T4 is reached, individual lines may be discharged. The potentials of the discharged lines may be decreased to the ground voltage GND or 0 V.

Referring to FIGS. 5A and 5B, when the selected word line Sel_WL is a sixth word line WL6 adjacent to the second dummy line group 2DWLG, among word lines included in the first word line group 1WLG, a third pass voltage 3Vpass higher than the second pass voltage 2Vpass may be applied to the second dummy line group 2DWLG during a partial period in which a program operation is performed so as to easily increase the channel voltages of unselected strings. That is, when there is no unselected word line Unsel_WL between the selected word line Sel_WL and the second dummy line group 2DWLG, the third pass voltage 3Vpass higher than the second pass voltage 2Vpass may be applied to the second dummy line group 2DWLG during a partial period in which the program operation is performed. The voltages applied to the lines during the program operation are sequentially described as follows.

During a period from T1 to T2, a program-enable voltage Val or a program-inhibit voltage Vinh may be applied to the bit lines BL. For example, the program-enable voltage Val may be applied to selected bit lines coupled to selected strings, and the program-inhibit voltage Vinh may be applied to unselected bit lines coupled to unselected strings.

The program-enable voltage Val may be set to a level equal to that of a ground voltage GND, and the program-inhibit voltage Vinh may be set to a positive voltage higher than the program-enable voltage Val. Although, in FIG. 5B, the program-inhibit voltage Vinh is illustrated as being applied to bit lines BL at a time point T1, the program-inhibit voltage Vinh may be applied to the bit lines BL from before the time point T1.

In order to control the channel voltages of strings according to the program-enable voltage Val or the program-inhibit voltage Vinh applied to the bit lines BL, a turn-on voltage Von may be applied to a drain select line group DSLG. The turn-on voltage Von may be set to a positive voltage so as to turn on first and second drain select transistors DST1 and DST2. When the ground voltage GND is applied to the source line SL, a turn-off voltage Voff may be applied to the source select line group SSLG so as to electrically disconnect the source line SL from the channels of the strings. The turn-off voltage Voff may be set to the ground voltage GND so as to turn off the first to third source select transistors SST1 to SST3.

The first pass voltage 1Vpass may be applied to first and third dummy line groups 1DWLG and 3DWLG, and the second pass voltage 2Vpass, higher than the first pass voltage 1Vpass, may be applied to the second dummy line group 2DWLG. In order to form channels in the strings, the second pass voltage Vpass2 may be applied to the unselected word lines Unsel_WL included in first and second word line groups 1WLG and 2WLG, and may also be applied to the selected word line Sel_WL included in the first word line group 1WLG. Due to the voltages applied to the respective lines during the period from T1 to T2, the channel voltages of the unselected strings may be increased.

During the period from T2 to T3, a program voltage Vpgm may be applied to the selected word line Sel_WL. Because the program voltage Vpgm is a voltage for increasing the threshold voltages of the selected memory cells, it may be set to a voltage higher than the second pass voltage 2Vpass. When the program voltage Vpgm is applied to the selected word lines Sel_WL, the third pass voltage 3Vpass higher than the second pass voltage 2Vpass may be applied to the second dummy line group 2DWLG, and the voltages applied to the remaining lines may be maintained at the voltages applied during the period from T1 to T2. The third pass voltage 3Vpass may be set to a voltage that is higher than the second pass voltage 2Vpass and lower than the program voltage Vpgm.

A period from T3 to T4 may be a period during which the potential of the selected word line Sel_WL is to be stepwise decreased. For example, the voltage of the selected word line Sel_WL may be decreased to the second pass voltage 2Vpass.

At a time point T4, individual lines may be discharged. The potentials of the discharged lines may be decreased to the ground voltage GND or 0 V.

Referring to FIGS. 6A and 6B, when the selected word line Sel_WL is included in the first word line group 1WLG, unselected word lines Unsel_WL are disposed between the selected word line Sel_WL and the first dummy line group 1DWLG, and other unselected word lines Unsel_WL are disposed between the selected word line Sel_WL and the second dummy line group 2DWLG, some of the unselected word lines Unsel_WL may float during a partial period in which a program operation is performed so as to easily increase the channel voltages of unselected strings. For example, when the selected word line Sel_WL is a third word line WL3, first and second word lines WL1 and WL2 may be disposed between the selected word line Sel_WL and the first dummy line group 1DWLG, and fourth to sixth word lines WL4 to WL6 may be disposed between the selected word line Sel_WL and the second dummy line group 2DWLG. In the present embodiment, the first and second word lines WL1 and WL2 between the selected word line Sel_WL and the first dummy line group 1DWLG may be defined as a 1-1-th word line group 1-1WLG, and the fourth to sixth word lines WL4 to WL6 between the selected word line Sel_WL and the second dummy line group 2DWLG may be defined as a 1-2-th word line group 1-2WLG. In order to prevent the channel voltages of unselected strings corresponding to the 1-2-th word line group 1-2WLG between the selected word line Sel_WL and the second dummy line group 2DWLG, among the word line groups, from decreasing, the unselected word lines Unsel_WL included in the 1-2-th word line group 1-2WLG may float. The voltages applied to the lines during the program operation are sequentially described as follows.

During a period from T1 to T2, a program-enable voltage Val or a program-inhibit voltage Vinh may be applied to the bit lines BL. For example, the program-enable voltage Val may be applied to selected bit lines coupled to selected strings, and the program-inhibit voltage Vinh may be applied to unselected bit lines coupled to unselected strings.

The program-enable voltage Val may be set to a level equal to that of a ground voltage GND, and the program-inhibit voltage Vinh may be set to a positive voltage higher than the program-enable voltage Val. Although, in FIG. 6B, the program-inhibit voltage Vinh is illustrated as being applied to bit lines BL at a time point T1, the program-inhibit voltage Vinh may be applied to the bit lines BL from before the time point T1.

In order to control the channel voltages of strings according to the program-enable voltage Val or the program-inhibit voltage Vinh applied to the bit lines BL, a turn-on voltage Von may be applied to a drain select line group DSLG. The turn-on voltage Von may be set to a positive voltage so as to turn on first and second drain select transistors DST1 and DST2. When the ground voltage GND is applied to the source line SL, a turn-off voltage Voff may be applied to the source select line group SSLG so as to electrically disconnect the source line SL from the channels of the strings. The turn-off voltage Voff may be set to the ground voltage GND so as to turn off the first to third source select transistors SST1 to SST3.

The first pass voltage 1Vpass may be applied to first and third dummy line groups 1DWLG and 3DWLG, and the second pass voltage 2Vpass, higher than the first pass voltage 1Vpass, may be applied to the second dummy line group 2DWLG. In order to form channels in the strings, the second pass voltage Vpass2 may be applied to the unselected word lines Unsel_WL included in the 1-1-th, 1-2-th, and second word line groups 1-1WLG, 1-2WLG, and 2WLG, and may also be applied to the selected word line Sel_WL. Due to the voltages applied to the respective lines during the period from T1 to T2, the channel voltages of the unselected strings may be increased.

During a period from T2 to T3, a program voltage Vpgm may be applied to the selected word line Sel_WL. Because the program voltage Vpgm is a voltage for increasing the threshold voltages of the selected memory cells, it may be set to a voltage higher than the second pass voltage 2Vpass. When the program voltage Vpgm is applied to the selected word lines Sel_WL, the third pass voltage 3Vpass higher than the second pass voltage 2Vpass may be applied to the second dummy line group 2DWLG, and the 1-2-th word line group 1-2WLG may float (FLT). When the unselected word lines Unsel_WL included in the 1-2-th word line group 1-2WLG are floating (FLT), the channel voltages of the unselected strings may be increased due to coupling between the floating 1-2-th word line group 1-2WLG and the channels. Due thereto, a phenomenon in which the threshold voltages of unselected memory cells included in the unselected strings are increased may be suppressed. The voltages applied to the remaining lines, other than the selected word line Sel_WL, the second dummy line group 2DWLG, and the 1-2-th word line group 1-2WLG, may be maintained at the voltages applied during the period from T1 to T2.

A period from T3 to T4 may be a period during which the potential of the selected word line Sel_WL is to be stepwise decreased. For example, the voltage of the selected word line Sel_WL may be decreased to the second pass voltage 2Vpass. Here, the second pass voltage 2Vpass may be applied again to the 1-2-th word line group 1-2WLG. Alternatively, the 1-2-th word line group 1-2WLG may remain floating (FLT).

At a time point T4, individual lines may be discharged. The potentials of the discharged lines may be decreased to the ground voltage GND or 0 V.

Referring to FIGS. 7A and 7B, when the selected word line Sel_WL is a first word line WL1 adjacent to the first dummy line group 1DWLG, among word lines included in the first word line group 1WLG, some of unselected word lines Unsel_WL may float during a partial period in which a program operation is performed so as to easily increase the channel voltages of unselected strings. For example, because a 1-1-th word line group 1-1WLG is not present between the selected word line Sel_WL and the first dummy line group 1DWLG, the second to sixth word lines WL2 to WL6 between the selected word line Sel_WL and the second dummy line group 2DWLG may be defined as a 1-2-th word line group 1-2WLG. In order to prevent the channel voltages of unselected strings corresponding to the 1-2-th word line group 1-2WLG from decreasing, the unselected word lines Unsel_WL included in the 1-2-th word line group 1-2WLG may float. The voltages applied to the lines during the program operation are sequentially described as follows.

During a period from T1 to T2, a program-enable voltage Val or a program-inhibit voltage Vinh may be applied to the bit lines BL. For example, the program-enable voltage Val may be applied to selected bit lines coupled to selected strings, and the program-inhibit voltage Vinh may be applied to unselected bit lines coupled to unselected strings.

The program-enable voltage Val may be set to a level equal to that of a ground voltage GND, and the program-inhibit voltage Vinh may be set to a positive voltage higher than the program-enable voltage Val. Although, in FIG. 7B, the program-inhibit voltage Vinh is illustrated as being applied to bit lines BL at a time point T1, the program-inhibit voltage Vinh may be applied to the bit lines BL from before the time point T1.

In order to control the channel voltages of strings according to the program-enable voltage Val or the program-inhibit voltage Vinh applied to the bit lines BL, a turn-on voltage Von may be applied to a drain select line group DSLG. The turn-on voltage Von may be set to a positive voltage so as to turn on first and second drain select transistors DST1 and DST2. When the ground voltage GND is applied to the source line SL, a turn-off voltage Voff may be applied to the source select line group SSLG so as to electrically disconnect the source line SL from the channels of the strings. The turn-off voltage Voff may be set to the ground voltage GND so as to turn off the first to third source select transistors SST1 to SST3.

The first pass voltage 1Vpass may be applied to first and third dummy line groups 1DWLG and 3DWLG, and the second pass voltage 2Vpass, higher than the first pass voltage 1Vpass, may be applied to the second dummy line group 2DWLG. In order to form channels in the strings, the second pass voltage Vpass2 may be applied to the unselected word lines Unsel_WL included in the 1-1-th, 1-2-th, and second word line groups 1-1WLG, 1-2WLG, and 2WLG, and may also be applied to the selected word line Sel_WL. Due to the voltages applied to the respective lines during the period from T1 to T2, the channel voltages of the unselected strings may be increased.

During the period from T2 to T3, a program voltage Vpgm may be applied to the selected word line Sel_WL. Because the program voltage Vpgm is a voltage for increasing the threshold voltages of the selected memory cells, it may be set to a voltage higher than the second pass voltage 2Vpass. When the program voltage Vpgm is applied to the selected word lines Sel_WL, the third pass voltage 3Vpass higher than the second pass voltage 2Vpass may be applied to the second dummy line group 2DWLG, and the 1-2-th word line group 1-2WLG may float (FLT). When the unselected word lines Unsel_WL included in the 1-2-th word line group 1-2WLG are floating (FLT), the channel voltages of the unselected strings may be increased due to coupling between the floating 1-2-th word line group 1-2WLG and the channels. Due thereto, a phenomenon in which the threshold voltages of unselected memory cells included in the unselected strings are increased may be suppressed. The voltages applied to the remaining lines, other than the selected word line Sel_WL, the second dummy line group 2DWLG, and the 1-2-th word line group 1-2WLG, may be maintained at the voltages applied during the period from T1 to T2.

A period from T3 to T4 may be a period during which the potential of the selected word line Sel_WL is to be stepwise decreased. For example, the voltage of the selected word line Sel_WL may be decreased to the second pass voltage 2Vpass. Here, the second pass voltage 2Vpass may be applied again to the 1-2-th word line group 1-2WLG. Alternatively, the 1-2-th word line group 1-2WLG may remain floating (FLT).

At a time point T4, individual lines may be discharged. The potentials of the discharged lines may be decreased to the ground voltage GND or 0 V.

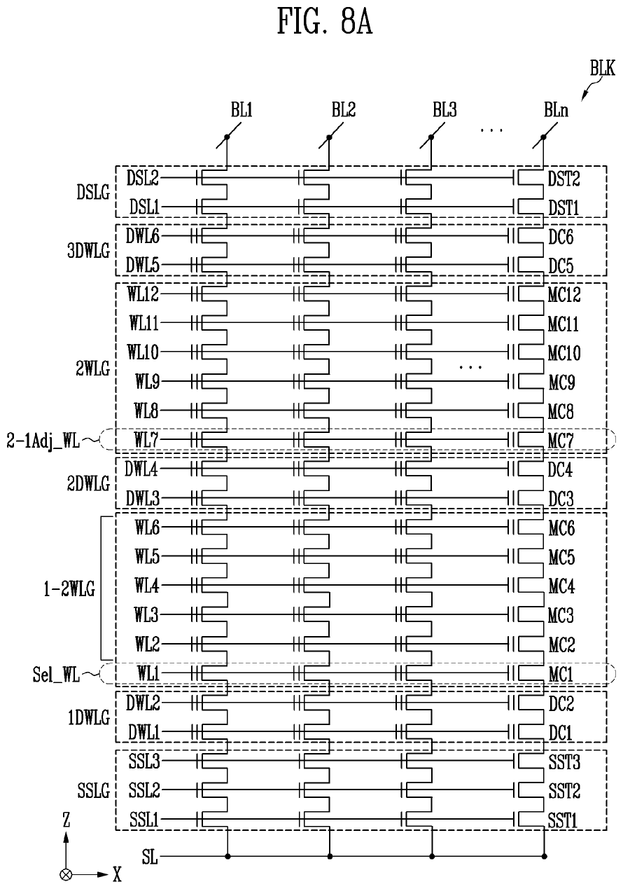

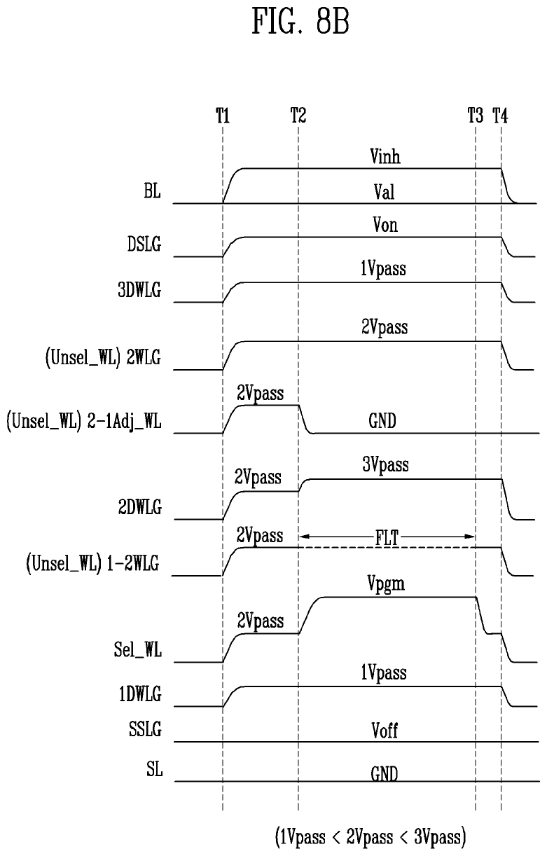

FIGS. 8A and 8B are diagrams illustrating a program operation according to a second embodiment of the present disclosure.

In the second embodiment, when a selected word line Sel_WL is included in a second word line group 2WLG, the program operation may be performed in the same manner as the program operation described with reference to FIGS. 4A and 4B. Therefore, the program operation to be described with reference to FIGS. 8A and 8B may be an additional embodiment of the program operation described above with reference to FIGS. 5A to 7B.

Referring to FIG. 8A, when the selected word line Sel_WL is disposed between first and second dummy line groups 1DWLG and 2DWLG, the voltage of a 2-1-th adjacent word line 2-1Adj_WL adjacent to the second dummy line group 2DWLG, among unselected word lines included in a second word line group 2WLG, may be decreased during a partial period of a program operation, in order to prevent the channel voltages of unselected strings from decreasing or to increase the channel voltages of the unselected strings.

Referring to FIG. 8B, during the program operation according to the second embodiment, the remaining operations, other than an operation of applying voltages to the 2-1-th adjacent word line 2-1Adj_WL, may be performed in a manner similar to that of the program operation according to the first embodiment described above with reference to FIG. 7B. Thus, repeated descriptions identical to those in the program operation described above with reference to FIG. 7B will be omitted.

During a period from T2 to T3, when a program voltage Vpgm is applied to the selected word line Sel_WL, the 2-1-th adjacent word line 2-1Adj_WL adjacent to the second dummy line group 2DWLG may be discharged. For example, the potential of the discharged 2-1-th adjacent word line 2-1Adj_WL may be decreased to a ground voltage GND. When the potential of the discharged 2-1-th adjacent word line 2-1Adj_WL is decreased to the ground voltage GND, unselected memory cells coupled to the 2-1-th adjacent word line 2-1Adj_WL are turned off, and thus a channel area between the turned-off unselected memory cells and turned-off source select transistors may float. In this case, because positive voltages having various levels are applied to the second dummy line group 2DWLG, the 1-2-th word line group 1-2WLG, the selected word line Sel_WL, and the first dummy line group 1DWLG, boosting may occur in the floating channel area, thus increasing channel voltages.

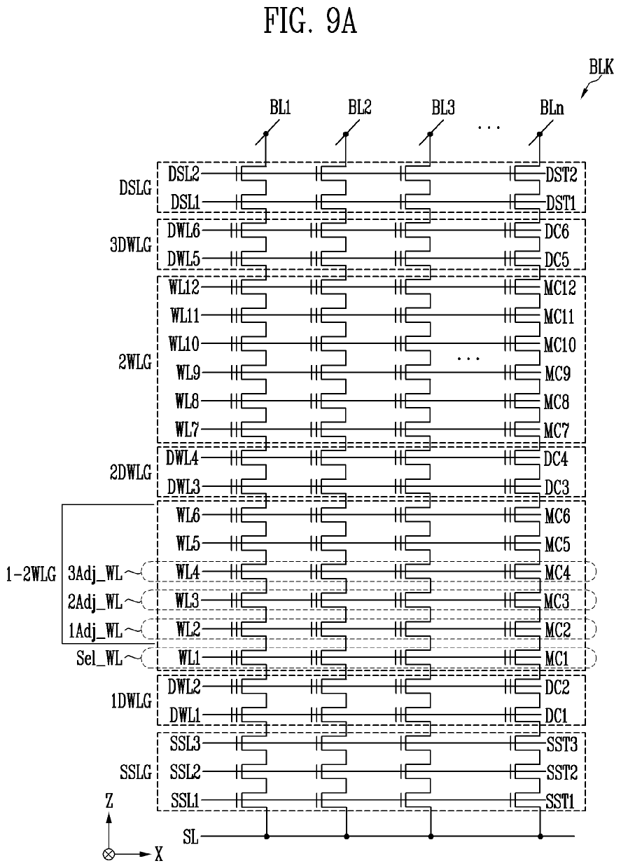

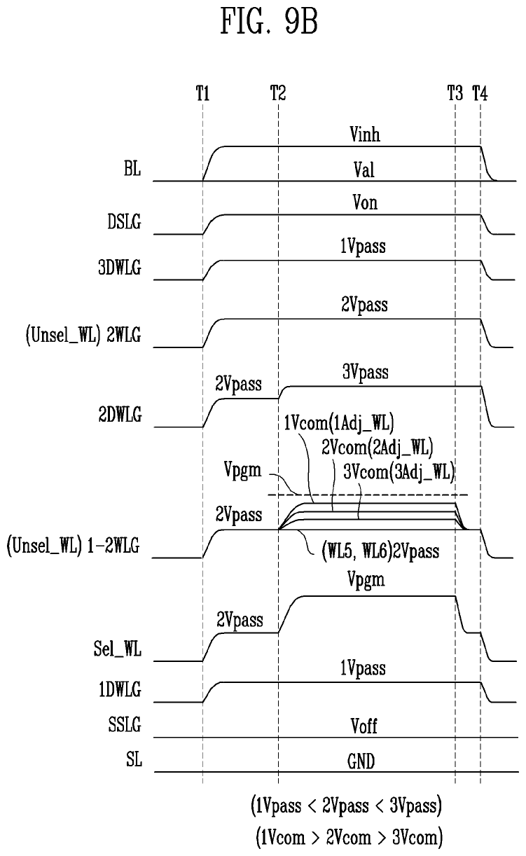

FIGS. 9A and 9B are diagrams illustrating a program operation according to a third embodiment of the present disclosure.

In the third embodiment, when a selected word line Sel_WL is included in a second word line group 2WLG, the program operation may be performed in the same manner as the program operation described with reference to FIGS. 4A and 4B. Therefore, the program operation to be described with reference to FIGS. 9A and 9B may be an additional embodiment of the program operation described above with reference to FIGS. 5A to 7B.

Referring to FIG. 9A, when the selected word line Sel_WL is disposed between first and second dummy line groups 1DWLG and 2DWLG, compensation voltages may be applied to first to third adjacent word lines 1Adj_WL to 3Adj_WL, which are sequentially adjacent to the selected word line Sel_WL, among unselected word lines included in the 1-2-th word line group 1-2WLG, during a partial period of a program operation in order to prevent the channel voltages of unselected strings from decreasing or to increase the channel voltages of the unselected strings.

Referring to FIG. 9B, during the program operation according to the third embodiment, the remaining operations, other than the operation of applying voltages to the first to third adjacent word lines 1Adj_WL to 3Adj_WL, which are sequentially adjacent to the selected word line Sel_WL among the unselected word lines, may be performed in a manner similar to that of the program operation according to the first embodiment described above with reference to FIG. 7B. For example, the first adjacent word line 1Adj_WL may be an unselected word line adjacent to the selected word line Sel_WL, the second adjacent word line 2Adj_WL may be an unselected word line adjacent to the first adjacent word line 1Adj_WL, and the third adjacent word line 3Adj_WL may be an unselected word line adjacent to the second adjacent word line 2Adj_WL. Thus, in the program operation according to the third embodiment, repeated descriptions identical to those in the program operation described above with reference to FIG. 7B will be omitted.

During a period from T2 to T3, when a program voltage Vpgm is applied to the selected word line Sel_WL, first to third compensation voltages 1Vcom to 3Vcom may be applied to the first to third adjacent word lines 1Adj_WL to 3Adj_WL. For example, the first compensation voltage 1Vcom may be applied to the first adjacent word line 1Adj_WL, and may be set to a voltage that is higher than a second pass voltage 2Vpass and lower than the program voltage Vpgm. The second compensation voltage 2Vcom may be applied to the second adjacent word line 2Adj_WL, and may be set to a voltage that is higher than the second pass voltage 2Vpass and lower than the first compensation voltage 1Vcom. The third compensation voltage 3Vcom may be applied to the third adjacent word line 3Adj_WL, and may be set to a voltage that is higher than the second pass voltage 2Vpass and lower than the first compensation voltage 1Vcom. The fifth and sixth word lines WL5 and WL6, other than the first to third adjacent word lines 1Adj_WL to 3Adj_WL, among the unselected word lines Unsel_WL between the selected word line Sel_WL and the second dummy line group 2DWLG, may be maintained at the second pass voltage 2Vpass applied during the period from T1 to T2.

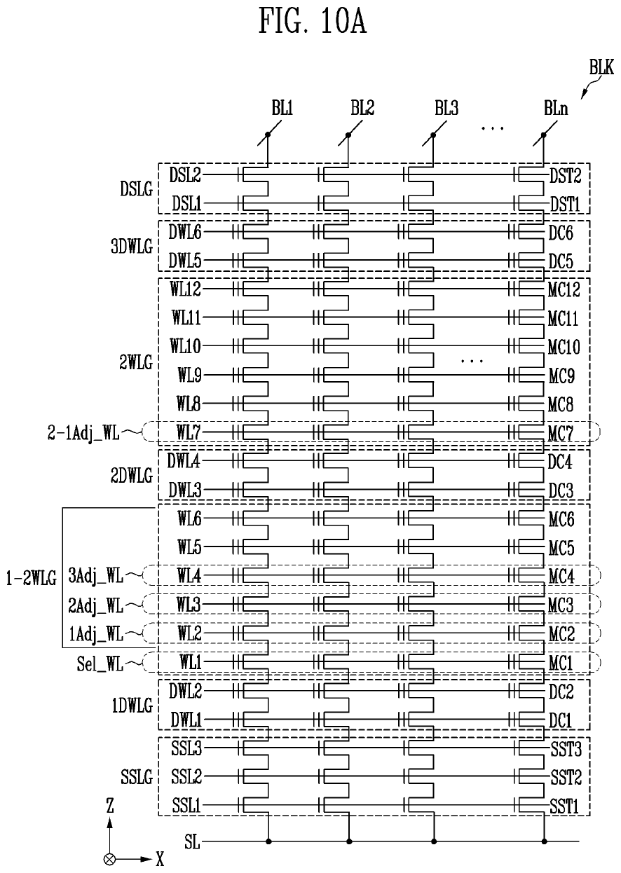

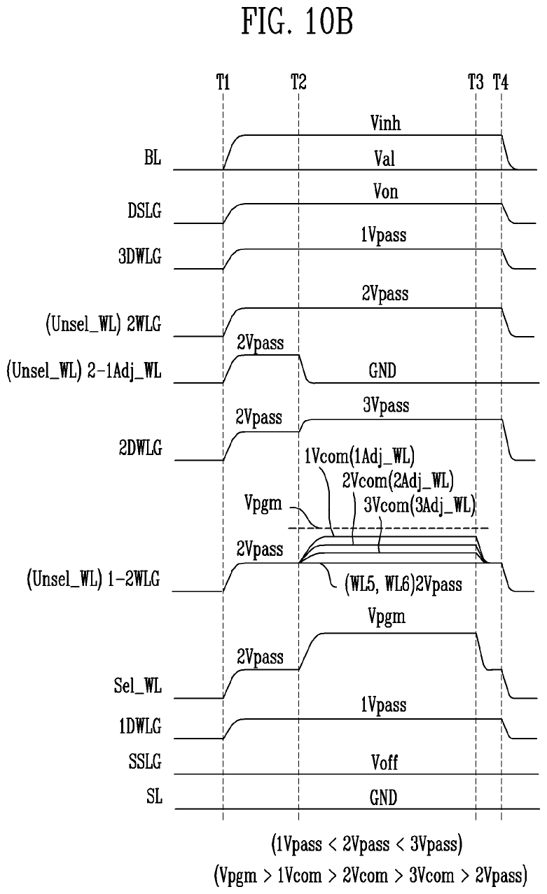

FIGS. 10A and 10B are diagrams illustrating a program operation according to a fourth embodiment of the present disclosure.

In the fourth embodiment, when a selected word line Sel_WL is included in a second word line group 2WLG, the program operation may be performed in the same manner as the program operation described with reference to FIGS. 4A and 4B. Therefore, the program operation to be described with reference to FIGS. 10A and 10B may be an additional embodiment of the program operation described above with reference to FIGS. 5A to 7B.

Referring to FIG. 10A, when the selected word line Sel_WL is disposed between first and second dummy line groups 1DWLG and 2DWLG, the voltage of a 2-1-th adjacent word line 2-1Adj_WL adjacent to the second dummy line group 2DWLG, among unselected word lines included in a second word line group 2WLG, may be decreased during a partial period of a program operation, in order to prevent the channel voltages of unselected strings from decreasing or to increase the channel voltages of the unselected strings. Further, compensation voltages may be applied to first to third adjacent word lines 1Adj_WL to 3Adj_WL, which are sequentially adjacent to the selected word line Sel_WL, among unselected word lines included in the 1-2-th word line group 1-2WLG.

Referring to FIG. 10B, during the program operation according to the fourth embodiment, the remaining operations other than the operation of applying the voltage to the 2-1-th adjacent word line 2-1Adj_WL and the operation of applying voltages to the first to third adjacent word lines 1Adj_WL to 3Adj_WL, which are sequentially adjacent to the selected word line Sel_WL among the unselected word lines, may be performed in a manner similar to that of the program operation according to the first embodiment described above with reference to FIG. 7B. Thus, repeated descriptions identical to those in the program operation described above with reference to FIG. 7B will be omitted.

During the period from T2 to T3, when the program voltage Vpgm is applied to the selected word line Sel_WL, the 2-1-th adjacent word line 2-1Adj_WL adjacent to the second dummy line group 2DWLG may be discharged. For example, the potential of the discharged 2-1-th adjacent word line 2-1Adj_WL may be decreased to the ground voltage GND.

During the period from T2 to T3, when a program voltage Vpgm is applied to the selected word line Sel_WL, first to third compensation voltages 1Vcom to 3Vcom may be applied to the first to third adjacent word lines 1Adj_WL to 3Adj_WL. For example, the first compensation voltage 1Vcom may be applied to the first adjacent word line 1Adj_WL, and may be set to a voltage that is higher than a second pass voltage 2Vpass and lower than the program voltage Vpgm. The second compensation voltage 2Vcom may be applied to the second adjacent word line 2Adj_WL, and may be set to a voltage that is higher than the second pass voltage 2Vpass and lower than the first compensation voltage 1Vcom. The third compensation voltage 3Vcom may be applied to the third adjacent word line 3Adj_WL, and may be set to a voltage that is higher than the second pass voltage 2Vpass and lower than the first compensation voltage 1Vcom. The fifth and sixth word lines WL5 and WL6, other than the first to third adjacent word lines 1Adj_WL to 3Adj_WL, among the unselected word lines Unsel_WL between the selected word line Sel_WL and the second dummy line group 2DWLG, may be maintained at the second pass voltage 2Vpass applied during the period from T1 to T2.

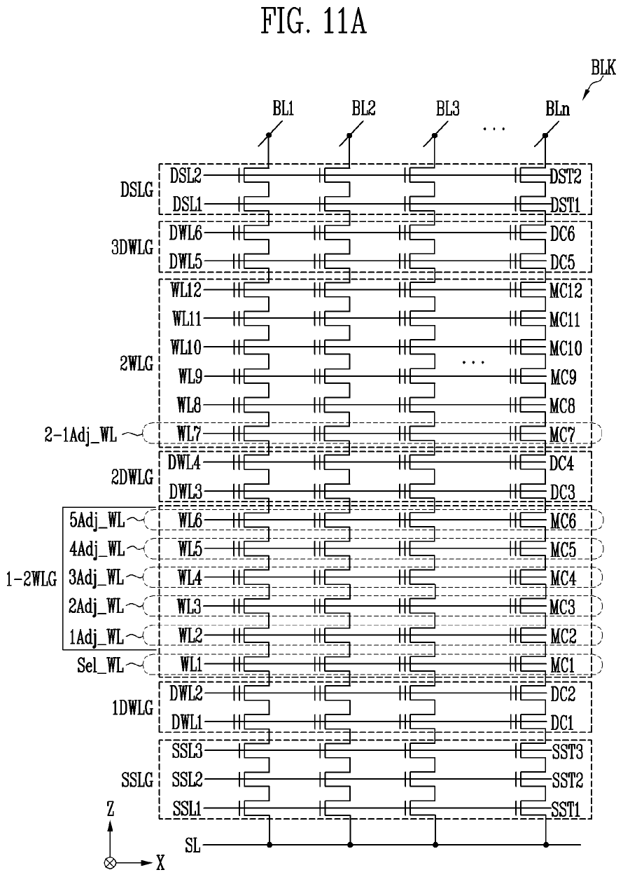

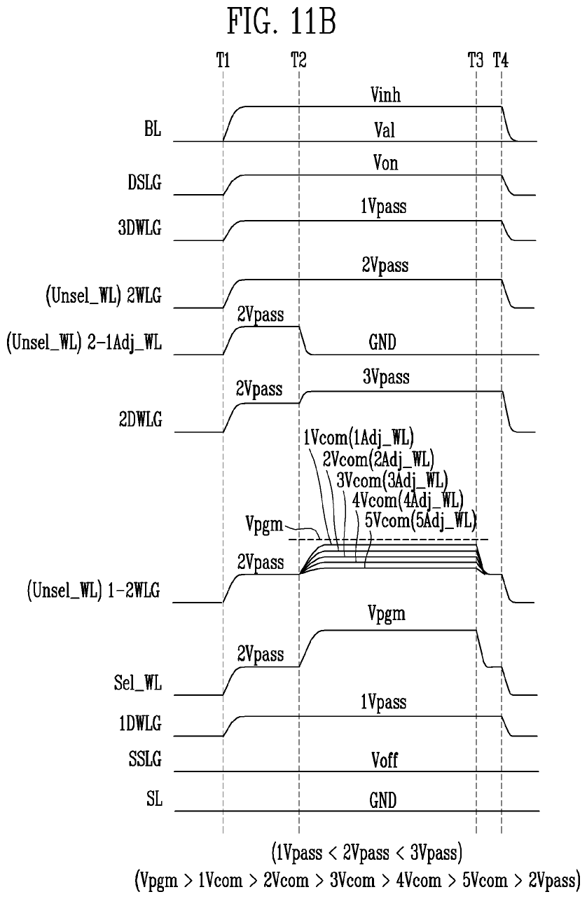

FIGS. 11A and 11B are diagrams illustrating a program operation according to a fifth embodiment of the present disclosure.

In the fifth embodiment, when a selected word line Sel_WL is included in a second word line group 2WLG, the program operation may be performed in the same manner as the program operation described with reference to FIGS. 4A and 4B. Therefore, the program operation to be described with reference to FIGS. 11A and 11B may be an additional embodiment of the program operation described above with reference to FIGS. 5A to 7B.

Referring to FIG. 11A, when the selected word line Sel_WL is disposed between first and second dummy line groups 1DWLG and 2DWLG, the voltage of a 2-1-th adjacent word line 2-1Adj_WL adjacent to the second dummy line group 2DWLG, among unselected word lines included in a second word line group 2WLG, may be decreased during a partial period of a program operation, in order to prevent the channel voltages of unselected strings from decreasing or to increase the channel voltages of the unselected strings. Further, a compensation voltage may be applied to all unselected word lines included in a 1-2-th word line group 1-2WLG. For example, when the total number of unselected word lines included in the 1-2-th word line group 1-2WLG is 5, the five unselected word lines may be defined as first to fifth adjacent word lines 1Adj_WL to 5Adj_WL. During the program operation, different compensation voltages may be applied to the first to fifth adjacent word lines 1Adj_WL to 5Adj_WL, respectively.

Referring to FIG. 11B, during the program operation according to the fifth embodiment, the remaining operations, other than an operation of applying a voltage to the 2-1-th adjacent word line 2-1Adj_WL and an operation of applying a voltage to the 1-2-th word line group 1-2WLG, may be performed in a manner similar to that of the program operation according to the first embodiment described above with reference to FIG. 7B. Thus, repeated descriptions identical to those in the program operation described above with reference to FIG. 7B will be omitted.

During a period from T2 to T3, when the program voltage Vpgm is applied to the selected word line Sel_WL, the 2-1-th adjacent word line 2-1Adj_WL adjacent to the second dummy line group 2DWLG may be discharged. For example, the potential of the discharged 2-1-th adjacent word line 2-1Adj_WL may be decreased to the ground voltage GND.

During the period from T2 to T3, when the program voltage Vpgm is applied to the selected word line Sel_WL, first to fifth compensation voltages 1Vcom to 5Vcom may be applied to first to fifth adjacent word lines 1Adj_WL to 5Adj_WL disposed between the selected word line Sel_WL and the second dummy line group 2DWLG. For example, the first compensation voltage 1Vcom may be applied to the first adjacent word line 1Adj_WL, and may be set to a voltage that is higher than a second pass voltage 2Vpass and lower than the program voltage Vpgm. The second compensation voltage 2Vcom may be applied to the second adjacent word line 2Adj_WL, and may be set to a voltage that is higher than the second pass voltage 2Vpass and lower than the first compensation voltage 1Vcom. The third compensation voltage 3Vcom may be applied to the third adjacent word line 3Adj_WL, and may be set to a voltage that is higher than the second pass voltage 2Vpass and lower than the first compensation voltage 1Vcom. That is, as the corresponding word line is farther away from the selected word line Sel_WL, a lower compensation voltage may be applied thereto. The fifth compensation voltage 5Vcom, which is the lowest compensation voltage among the first to fifth compensation voltages 1Vcom to 5Vcom, may be set to a voltage higher than the second pass voltage 2Vpass.

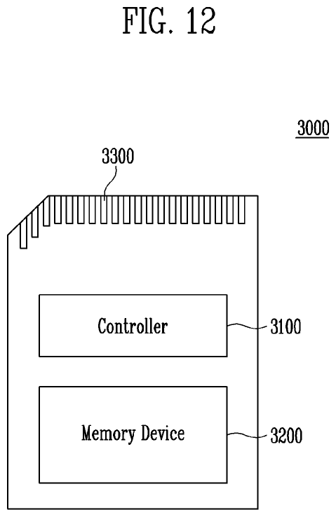

FIG. 12 is a diagram illustrating a memory card system to which a memory device according to the present disclosure is applied.

Referring to FIG. 12, a memory card system 3000 may include a controller 3100, a memory device 3200, and a connector 3300.

The controller 3100 may be coupled to the memory device 3200. The controller 3100 may access the memory device 3200. For example, the controller 3100 may control a program, a read, or an erase operation of the memory device 3200, or may control a background operation of the memory device 3200. The controller 3100 may provide an interface between the memory device 3200 and a host. The controller 3100 may run firmware for controlling the memory device 3200. In an example, the controller 3100 may include components, such as random access memory (RAM), a processor, a host interface, a memory interface, and an error correction block.

The controller 3100 may communicate with an external device through the connector 3300. The controller 3100 may communicate with an external device (e.g., a host) based on a specific communication standard. In an embodiment, the controller 3100 may communicate with the external device through at least one of various communication standards such as universal serial bus (USB), multimedia card (MMC), embedded MMC (eMMC), peripheral component interconnection (PCI), PCI-express (PCI-E), advanced technology attachment (ATA) protocol, serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). In an embodiment, the connector 3300 may be defined by at least one of the above-described various communication standards.

The memory device 3200 may include a plurality of memory cells, and may be configured in the same manner as the memory device 100 illustrated in FIG. 1. Therefore, the memory device 3200 may control the voltages that are applied to unselected word lines or dummy lines during a program operation.

The controller 3100 and the memory device 3200 may be integrated into a single semiconductor device to form a memory card. For example, the controller 3100 and the memory device 3200 may be integrated into a single semiconductor device, and may then form a memory card such as a personal computer memory card international association (PCMCIA) card, a compact flash card (CF), a smart media card (SM or SMC), a memory stick, a multimedia card (MMC, RS-MMC, MMCmicro or eMMC), an SD card (SD, miniSD, microSD, or SDHC), or a universal flash storage (UFS).

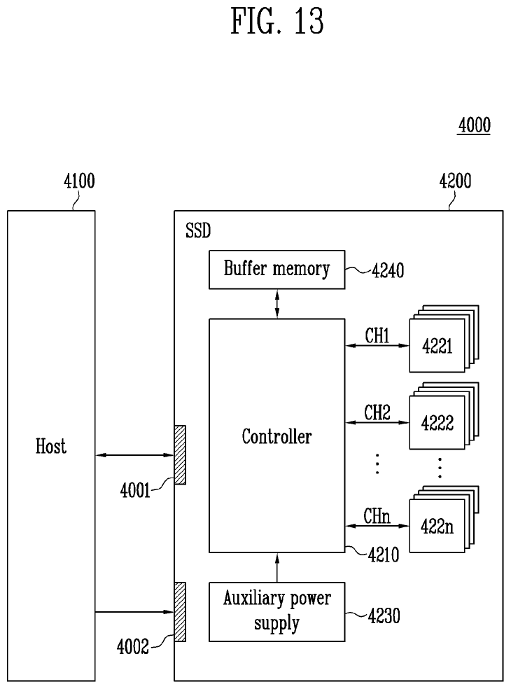

FIG. 13 is a diagram illustrating a solid state drive (SSD) system to which a memory device according to the present disclosure is applied.

Referring to FIG. 13, an SSD system 4000 may include a host 4100 and an SSD 4200. The SSD 4200 may exchange a signal with the host 4100 through a signal connector 4001, and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. In an embodiment, the received signals may be signals based on the interfaces of the host 4100 and the SSD 4200. For example, the signals may be defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n may include a plurality of memory cells configured to store data. Each of the memory devices 4221 to 422n may be configured in the same manner as the memory device 100 illustrated in FIG. 1. Therefore, each of the plurality of memory devices 4221 to 422n may control the voltages that are applied to unselected word lines or dummy lines during a program operation. The plurality of memory devices 4221 to 422n may communicate with the controller 4210 through channels CH1 to CHn.

The auxiliary power supply 4230 may be coupled to the host 4100 through the power connector 4002. The auxiliary power supply 4230 may be supplied with a supply voltage from the host 4100, and may be charged. The auxiliary power supply 4230 may provide the supply voltage of the SSD 4200 when the supply of power from the host 4100 is not smoothly performed. In an embodiment, the auxiliary power supply 4230 may be located inside the SSD 4200 or located outside the SSD 4200. For example, the auxiliary power supply 4230 may be located in a main board, and may provide auxiliary power to the SSD 4200.

The buffer memory 4240 may function as buffer memory of the SSD 4200. For example, the buffer memory 4240 may temporarily store data received from the host 4100 or data received from the plurality of memory devices 4221 to 422n, or may temporarily store metadata (e.g., mapping tables) of the memory devices 4221 to 422n. The buffer memory 4240 may include volatile memory, such as dynamic random access memory (DRAM), synchronous DRAM (SDRAM), double data rate (DDR) SDRAM, and low power DDR (LPDDR) SDRAM, or nonvolatile memory, such as ferroelectric RAM (FRAM), resistive RAM (ReRAM), spin transfer torque magnetic RAM (STT-MRAM), and phase-change RAM (PRAM).

The present disclosure may improve the reliability of a program operation performed on a memory device.

What is claimed is:

1. A memory device, comprising:
a memory block to which first and second word line groups are coupled, and to which a first dummy line group disposed between the first and second word line groups is coupled; and
a peripheral circuit configured to program memory cells coupled to a selected word line of the first or second word line group,
wherein the peripheral circuit is configured to:
when the selected word line is included in the second word line group, when a program voltage is applied to the selected word line, apply a first pass voltage to unselected word lines included in the first and second word line groups and to dummy lines included in the first dummy line group, and
when the selected word line is included in the first word line group, when the program voltage is applied to the selected word line, allow first unselected word lines disposed between the selected word line and the first dummy line group to float, apply the first pass voltage to second unselected word lines other than the selected word line and the first unselected word lines among word lines included in the first word line group, and apply a second pass voltage higher than the first pass voltage to the dummy lines included in the first dummy line group.

2. The memory device according to claim 1, wherein:
the first word line group is adjacent to a source line, and
the second word line group is adjacent to bit lines.

3. The memory device according to claim 2, further comprising:
a second dummy line group disposed between the first word line group and the source line; and
a third dummy line group disposed between the second word line group and the bit lines.

4. The memory device according to claim 3, wherein the peripheral circuit is configured to, when the program voltage is applied to the selected word line included in the first word line group, apply a third pass voltage lower than the first pass voltage to the second and third dummy line groups.

5. The memory device according to claim 4, wherein the peripheral circuit is configured to, before the program voltage is applied to the selected word line included in the first word line group, apply the third pass voltage to the second and third dummy line groups.

6. The memory device according to claim 1, wherein the peripheral circuit is configured to, before the program voltage is applied to the selected word line included in the first word line group, apply the first pass voltage to unselected word lines included in the first and second word line groups and to the selected word line.

7. The memory device according to claim 1, wherein the peripheral circuit is configured to, during the program voltage is applied to the selected word line included in the first word line group, decrease a voltage of an unselected word line adjacent to the first dummy line group among word lines included in the second word line group.

8. A method of operating a memory device, the method comprising:
when a first word line group and a second word line group are located between a source line and bit lines, wherein the first word line group is adjacent to the source line, and the second word line group is adjacent to bit lines, and a selected word line is included in the first word line group, applying a program voltage to the selected word line;
when the program voltage is applied to the selected word line, applying a first pass voltage to the second word line group;
when the program voltage is applied to the selected word line, applying a second pass voltage higher than the first pass voltage to a first dummy line group between the first and second word line groups; and
when the program voltage is applied to the selected word line, allowing unselected word lines between the selected word line and the first dummy line group to float.

9. The method according to claim 8, further comprising:
when the program voltage is applied to the selected word line, decreasing a voltage of an unselected word line adjacent to the first dummy line group among word lines included in the second word line group.

10. The method according to claim 8, further comprising:
before a program voltage is applied to the selected word line, applying the first pass voltage to unselected word lines included in the first and second word line groups and to the selected word line.

11. The method according to claim 8, further comprising:
when the program voltage is applied to the selected word line, applying a third pass voltage lower than the first pass voltage to a second dummy line group between the first word line group and the source line and to a third dummy line group between the second word line group and the bit lines.

12. A memory device, comprising:
a memory block to which first and second word line groups are coupled, and to which a first dummy line group disposed between the first and second word line groups is coupled; and
a peripheral circuit configured to program memory cells coupled to a selected word line of the first or second word line group,
wherein the peripheral circuit is configured to:
when the selected word line is included in the second word line group, when a program voltage is applied to the selected word line, apply a first pass voltage to unselected word lines included in the first and second word line groups and to dummy lines included in the first dummy line group, and
when the selected word line is included in the first word line group, when the program voltage is applied to the selected word line, apply compensation voltages higher than the first pass voltage to first unselected word lines disposed between the selected word line and the first dummy line group, apply the first pass voltage to second unselected word lines other than the selected word line and the first unselected word lines among word lines included in the first word line group, and apply a second pass voltage higher than the first pass voltage to the dummy lines included in the first dummy line group.

13. The memory device according to claim 12, wherein the peripheral circuit is configured to control levels of the compensation voltages depending on distances between the selected word line and the first unselected word lines.

14. The memory device according to claim 12, wherein the peripheral circuit is configured to set the compensation voltages to higher voltages as distances between the selected word line and the first unselected word lines become shorter.

15. The memory device according to claim 12, wherein the peripheral circuit is configured to set levels of the compensation voltages to levels lower than that of the program voltage.

16. The memory device according to claim 12, further comprising:
a second dummy line group disposed between the first word line group and the source line; and
a third dummy line group disposed between the second word line group and the bit lines.

17. The memory device according to claim 16, wherein the peripheral circuit is configured to, when the program voltage is applied to the selected word line included in the first word line group, apply a third pass voltage lower than the first pass voltage to the second and third dummy line groups.

18. The memory device according to claim 17, wherein the peripheral circuit is configured to, before the program voltage is applied to the selected word line included in the first word line group, apply the third pass voltage to the second and third dummy line groups.

19. The memory device according to claim 12, wherein the peripheral circuit is configured to, before the program voltage is applied to the selected word line included in the first word line group, apply the first pass voltage to unselected word lines included in the first and second word line groups and to the selected word line.

20. The memory device according to claim 12, wherein the peripheral circuit is configured to, when the program voltage is applied to the selected word line included in the first word line group, decrease a voltage of an unselected word line adjacent to the first dummy line group among word lines included in the second word line group.

21. A method of operating a memory device, the method comprising:
when a first word line group and a second word line group are located between a source line and bit lines, wherein the first word line group is adjacent to the source line, and the second word line group is adjacent to bit lines, and a selected word line is included in the first word line group, applying a program voltage to the selected word line;
when the program voltage is applied to the selected word line, applying a first pass voltage to the second word line group;
when the program voltage is applied to the selected word line, applying a second pass voltage higher than the first pass voltage to a first dummy line group between the first and second word line groups; and
when the program voltage is applied to the selected word line, applying compensation voltages higher than the first pass voltage to unselected word lines between the selected word line and the first dummy line group.

22. The method according to claim 21, further comprising:
when the program voltage is applied to the selected word line, decreasing a voltage of an unselected word line adjacent to the first dummy line group among word lines included in the second word line group.

23. The method according to claim 21, further comprising:
before a program voltage is applied to the selected word line, applying the first pass voltage to unselected word lines included in the first and second word line groups and to the selected word line.

24. The method according to claim 21, further comprising:
when the program voltage is applied to the selected word line, applying a third pass voltage lower than the first pass voltage to a second dummy line group between the first word line group and the source line and to a third dummy line group between the second word line group and the bit lines.
